(19) United States
(12) Patent Application Publication
(10) Pub. No.: US 2005/0268189 A1
(43) Pub. Date: Dec. 1, 2005

(54) Device testing using multiple test kernels

(75) Inventor: Donald C. Soltis JR., Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P.

(21) Appl. No.: 10/857,117

(22) Filed: May 28, 2004

(51) Int. Cl. G01R 31/28

(52) U.S. Cl. 714/724

(57) ABSTRACT

In a device testing arrangement, a data set is selected from a set of multiple data sets, and a test kernel is selected from a set of multiple test kernels. The test kernel includes one or more instructions that utilize data. The test kernel is executed with at least some of the data from the data set, which causes one or more inputs to be provided to a device under test. A test result is obtained as one or more results generated by the device under test in response to the executing. The data set and kernel selection, execution, and result obtaining processes are repeated for one or more remaining test kernels in the set of multiple test kernels and for one or more remaining data sets in the set of multiple data sets.

### BACKGROUND

A new integrated circuit design will likely undergo several test phases to verify its functionality and reliability, prior to releasing the new design on the market. Initially, a software simulation of the circuit design will be tested. When the design simulation is adequately verified, the circuit design may be released to manufacturing for prototype fabrication and further testing.

To ensure adequate design margins for timing paths, noise effects (e.g., coupling), and other electrical characteristics, hardware tests may include testing a design over various ranges of “process, voltage, and temperature,” or “PVT.” To test over “process” ranges, one or more processes used during manufacture of the test chips may intentionally be varied. Some intentional process-related variations include, for example, alignment variations (i.e., skews) between different layers of the integrated circuit, thickness variations of one or more layers, chemical composition variations, etching time variations, and/or deposition time variations, among other things. Depending on the numbers and combinations of processes that are varied, the ranges and granularities of those variations, and the numbers of chips to test for each process test iteration, hundreds or thousands of process-varied chips may need to be manufactured and tested in order to adequately verify a design.

Some or all of these chips additionally may be tested over various voltage and/or temperature ranges. The ranges and granularities of the voltage and temperature test iterations further multiply the number of tests that may be performed to verify a design. Accordingly, potentially millions of PVT test iterations may be performed during a design test cycle. When the testing cycle reveals unacceptable design flaws, failures and/or marginal performance, design modifications may be made, and all or portions of the design/test cycle may be repeated.

To test a single chip of a set of PVT-varied chips, a test program is executed in an attempt to activate some or all of the various circuit marginalities that may exist. To do so, the test program provides commands and data to the chip's pins and/or other test points. A test computer receives and analyzes the integrated circuit's responses to the input commands and data in order to detect unacceptable marginalities and/or failures. Complex integrated circuit designs call for extensive test programs to simulate the wide range of operational possibilities. Accordingly, test software is often lengthy and complex, and its execution may be time consuming.

Complex test software coupled with potentially millions of PVT test iteration variations may make the integrated circuit design verification process a long one. In order to shorten test cycle times and get products to market faster, integrated circuit test developers continuously strive to develop efficient and reliable methods and apparatus for testing and verifying integrated circuits.

### BRIEF DESCRIPTION OF THE DRAWINGS

Like-reference numbers refer to similar items throughout the figures and:

FIG. 1 illustrates a testing system, in accordance with an embodiment;

FIG. 2 illustrates a target system, in accordance with an embodiment;

FIG. 3 illustrates a flowchart of a procedure for testing an integrated circuit design, in accordance with an example embodiment;

FIG. 4 illustrates a flowchart of a procedure for establishing baseline test results, in accordance with an example embodiment;

FIG. 5 illustrates a flowchart of a procedure for performing a non-baseline test iteration, in accordance with an example embodiment;

FIG. 6 illustrates a flowchart of a procedure for performing a non-baseline test iteration, in accordance with another example embodiment;

FIG. 7 illustrates a flowchart of a procedure for performing a non-baseline test iteration, in accordance with another example embodiment;

FIG. 8 illustrates a flowchart of a procedure for evaluating marginal conditions, in accordance with an example embodiment;

FIG. 9 illustrates a flowchart of a procedure for generating test kernels, in accordance with an example embodiment; and

FIG. 10 illustrates a flowchart of a procedure for generating test data, in accordance with an example embodiment.

### DETAILED DESCRIPTION

Various embodiments of the described subject matter may be used to test physical implementations of integrated circuits. More specifically, embodiments may be used to detect and identify marginally-performing or failing electrical paths and/or electrical elements within an integrated circuit. Testing may be performed in a manner that increases efficiency and reliability.

In accordance with various embodiments, a set of kernels and multiple data sets are generated for use in testing a device under test (DUT). In an embodiment, selected kernels include relatively short “activation sequences” (i.e., relatively few instructions for activating portions of the DUT), and numerous kernels may be generated for a set of kernels. The multiple data sets are generated using one or more “phenomenon-directed” data generation algorithms, in an embodiment.

To perform a DUT test at a particular operating point, a device is selected and placed into the testing system, and a set of test conditions (e.g., frequency, voltage, and/or temperature) are established. During the test iteration, a test computer causes the DUT to execute the multiple kernels using the multiple data sets, thus activating various paths within the DUT. The DUT determines results produced by the DUT in response to executing the multiple kernels. In an embodiment, the DUT produces “result signatures,” which represent the test results. The DUT may communicate the result signatures to the test computer and/or the DUT may store the result signatures for later comparison with result signatures generated during another test iteration. The DUT and/or the test computer may determine if one or more marginal or failing electrical conditions exist for the DUT under the particular test conditions. In an embodiment, the kernel and/or data that caused the marginal performance or failing condition to occur can be pinpointed, thus aiding an analyzer of the information in determining where in the DUT and how the condition occurred. This information can be used to re-design the circuit to reduce or eliminate the marginal or failing condition.

Embodiments provide integrated circuit testing and detection of marginal performance and failing conditions. The term “marginal condition” is defined herein as a condition that produces marginal electrical performance (e.g., too fast, too slow, too noisy) and/or a failing condition (e.g., produces wrong signal, data, or result).

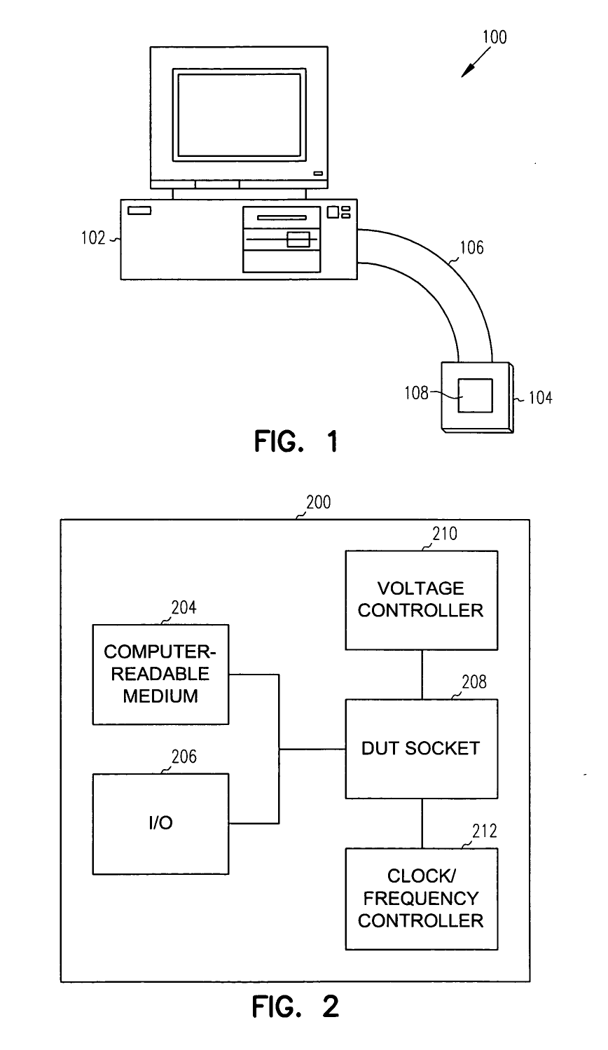

FIG. 1 illustrates testing system 100, in accordance with an embodiment. Testing system 100 includes a test controller computer 102, a target system 104, and one or more transmission media 106. To conduct a test, pins of a selected DUT 108 are secured within a socket of target system 104. Test conditions (e.g., frequency, voltage, and/or temperature) are established for the DUT 108. For example, test controller computer 102, target system 104, and/or other elements associated with system 100 may establish an operating voltage and/or a clock or signal frequency provided to the DUT 108. In addition, the ambient temperature may be adjusted, and the DUT permitted to stabilize for a time at that temperature.

Test controller computer 102 generates or receives a test program, which includes multiple “kernels” and multiple data sets, in an embodiment. The test program is provided to DUT 108 via target system 104. Test controller computer 102 further causes DUT 108 to execute the test program, and DUT 108 produces internal results. In an embodiment, DUT 108 further computes “result signatures,” which represent the internally-generated results. As will be described in more detail later, DUT 108 may store the result signatures (e.g., internally or elsewhere within the target system 104), and/or DUT 108 may send the result signatures back to the test computer 102. As will be described in more detail later, DUT 108 may further compare the result signatures to later-produced result signatures to determine whether marginal conditions may exist at one or more operating points.

Target system 104 receives signals from and sends signals to computer 102 over transmission media 106, in an embodiment. Transmission media 106 may include, for example, a circuit board connector, a computer connector, and a set of wires and/or cables that links the two connectors. Transmission media 106 supports signal exchanges between computer 102 and the socket contacts of target system 104. Accordingly, computer 102 may send signals to and receive signals from the DUT 108 through target system 104 and transmission media 106.

Test controller computer 102 may be a general-purpose or special-purpose computer, which is capable of executing software instructions that provide signals to and receive signals from DUT 108 via transmission media 106 and target system 104. In an embodiment, test controller computer 102 includes program instructions for a testing method. The program instructions may be stored within the test controller computer 102 (e.g., stored within random access memory (RAM), read-only memory (ROM), a hard drive, and/or a removable storage medium). In another embodiment, the program instructions may be stored within a computer-readable medium that is remote from test controller computer 102 (e.g., a server or other remote computer).

DUT 108 may be, for example, a microprocessor, a special-purpose processor, an application specific integrated circuit (ASIC), a memory device, a multi-chip module, or any of a number of other types of integrated circuits. In an embodiment, DUT 108 includes processing elements that enable DUT 108 to receive and execute one or more kernels, to compute one or more result signatures based on results of executing one or more kernels, to compare previously-computed result signatures with later-computed result signatures, and to communicate relevant test-related information to test computer 102 via test system 104.

As will be described in more detail later, when the program instructions are executed, they result in the test computer obtaining or generating multiple data sets and a set of multiple test kernels, in an embodiment. They further result in a DUT executing a selected test kernel with at least some of the data from the data sets, which causes the DUT to produce one or more test results, in an embodiment. They further result in the DUT producing one or more result signatures, which may be used to identify potentially marginal conditions. In an embodiment, the DUT repeats this process for each remaining test kernel in the set of multiple test kernels and for each remaining data set in the set of multiple data sets. The DUT and/or test controller computer may evaluate the results and/or result signatures and provide information that may enable testers to pinpoint sub-standard areas on the DUT for the given test conditions, in an embodiment.

FIG. 2 illustrates a target system 200 (e.g., target system 104, FIG. 1), in accordance with an embodiment. Target system 200 includes one or more computer-readable media 204 (indicated as “computer-readable medium“), one or more input/outputs (I/O) 206, and a DUT socket 208. In an embodiment, target system 200 additionally includes one or more adjustable devices, such as a voltage controller 210 and/or a clock/frequency controller 212, which may be manipulated to vary test conditions to which a DUT is subjected.

To conduct a test, connectors of a selected DUT are secured within DUT socket 208. In an embodiment, DUT socket 208 includes an integrated circuit device socket. For example, but not by way of limitation, socket 208 may include a microprocessor socket, a special-purpose processor socket, an ASIC socket, a memory device socket, a multi-chip module socket, or any of a number of other types of integrated circuit sockets.

DUT socket 208 includes pin contacts (not illustrated), which contact the DUT pins, when the DUT is inserted in the socket. This enables the socket 208 to provide signals, power, and ground to an inserted DUT, and to receive signals from the DUT. In an alternate embodiment, socket 208 may include contacts that enable signal, power, and ground exchange with a DUT having pads, bumps, or alternative types of connectors other than pins. The term “socket contact” is meant to include any type of conductive contact, on or within a socket, which can be brought into electrical contact with a corresponding DUT connector. The term “DUT connector” or “device connector” is meant to include any type of conductive connector, on or within a device, which can be brought into electrical contact with a corresponding socket contact.

Test conditions (e.g., frequency, voltage, and/or temperature) are established for the DUT. In an embodiment, this may include adjusting the operating voltage provided to the DUT using voltage controller 210, and/or adjusting the clock frequency or signal frequency provided to the DUT using clock/frequency controller 212. In addition, the ambient temperature may be adjusted, and the DUT permitted to stabilize for a time at that temperature. An inserted DUT (e.g., DUT 108, FIG. 1) receives and executes a test program (e.g., one or more kernels and data sets), and produces results. The program instructions may be stored on one or more computer-readable media 204 (e.g., RAM, ROM, a hard drive, and/or a removable storage medium) prior to execution, in an embodiment. In another embodiment, the DUT may receive some or all of the program instructions via I/O 206.

FIGS. 1 and 2 illustrate just two embodiments of a testing system and a target system in which embodiments may be practiced. Other types of systems for testing integrated circuits also exist. It will be appreciated by those of skill in the art, based on the description herein, how to modify the systems of FIGS. 1 or 2 or to adapt the embodiments to other types of testing systems, while still performing substantially the same functions, in substantially the same way, to achieve substantially the same result. Accordingly, the scope of the described subject matter is not meant to be strictly limited to those systems illustrated in FIGS. 1 and 2, but instead is meant to include alternate embodiments of testing systems.

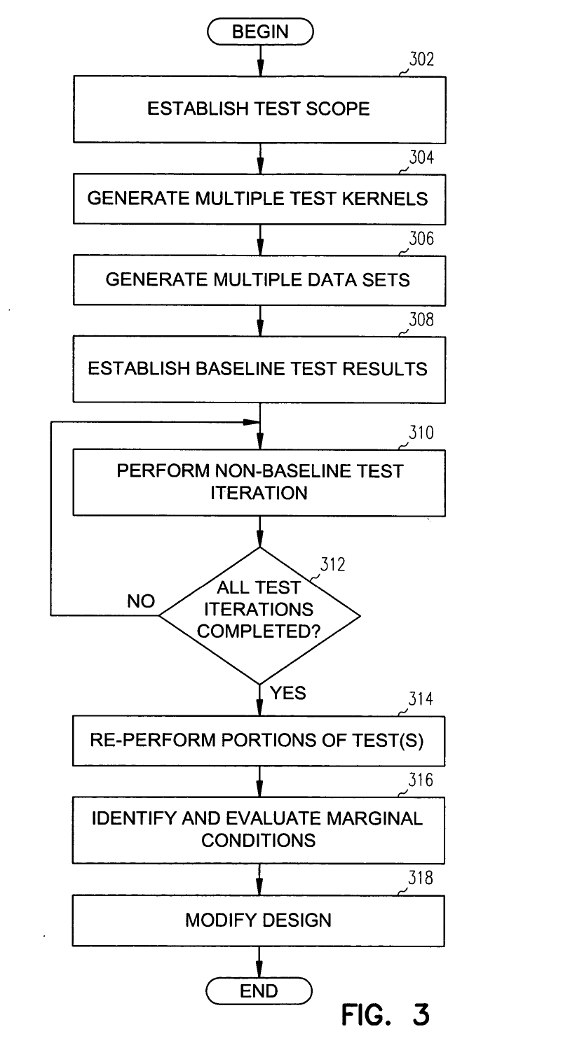

The remaining figures illustrate various procedures for implementing embodiments. FIG. 3 illustrates an overall method of performing a test of an integrated circuit design. This may include testing multiple devices over multiple operating points. A “test iteration” is defined herein as a complete test executed for a selected device that is subjected to a particular set of test conditions (i.e., specific settings for frequency, voltage, and/or temperature). A “test series” is a set of multiple test iterations. An “operating point” is defined herein to mean a set of test conditions having specific settings. When a test is executed for a new device and/or for the same device with a modified operating point (e.g., the frequency, temperature, and/or voltage are modified), the test is considered a distinct test iteration.

FIG. 3 illustrates a flowchart of a procedure for testing an integrated circuit design, in accordance with an embodiment. The method begins, in an embodiment, by establishing the scope of the test series, in block 302. In an embodiment, this includes defining the number and/or identities of the devices to be tested. The devices may have been manufactured using substantially the same processes and materials. Alternatively, a set of devices to test may include devices that have been manufactured using variable processing techniques and/or materials.

Establishing the scope of the test also may include establishing the ranges and granularities of operating frequency, operating voltage, operating temperature, and/or other conditions over which to test each device, in an embodiment. For example, but not by way of limitation, a test may be defined so that each device is tested from 100 Celsius (C.) to 40° C. at a granularity of 5° C. This would yield seven different temperature settings at which tests should be conducted. Test ranges and granularities similarly may be established for operating voltage, operating frequency, and/or other test conditions.

By establishing the test scope, the number of test iterations in the complete test procedure is defined. For example, if each of 50 devices is to be tested at 100 different operating points, then 5,000 test iterations may be included in the complete test procedure.

In block 304, a set of multiple test kernels is generated. In an embodiment, the set of multiple test kernels represents the instructions that will be executed during a test iteration. The set of multiple test kernels includes more than one kernel. In an embodiment, the set of multiple test kernels includes 100 or more test kernels, although fewer kernels may be included in a set, in other embodiments. As will be described in more detail later, the set of multiple test kernels may be executed one or more times during a test iteration.

In an embodiment, each kernel includes at least one activation sequence. An activation sequence is an instruction that, when executed, activates a particular portion of the circuitry within the DUT. The kernels are generated with the target type of DUT in mind. In other words, if a DUT to be tested includes an arithmetic logic unit (ALU), then the kernels may be generated to include adding, shifting, and other ALU-related instructions, which are intended to activate the ALU within the DUT. As another example, if a DUT to be tested is a microprocessor or memory controller, then the kernels may be generated to include load and store instructions.

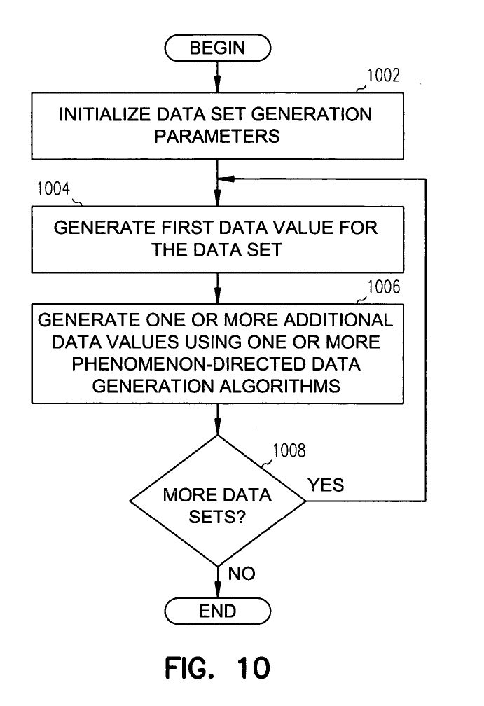

In an embodiment, some or all kernels include twenty or fewer instructions. In other embodiments, some or all kernels may include more than twenty instructions. As described below, using relatively short kernels facilitates pinpointing potential marginal conditions in the DUT. An embodiment of a method for generating a set of multiple test kernels is described in more detail later in conjunction with FIG. 9.

In block 306, multiple data sets are generated. In an embodiment, the multiple data sets represent the data that will be used while executing the test kernels. In an embodiment, the set of multiple data sets includes 1,000 or more data sets, although fewer data sets may be generated, in other embodiments.

As will be described in more detail later, each kernel may be executed for each data set, in an embodiment. Accordingly, if the set of multiple test kernels includes 100 kernels, and 8,000 data sets are generated, a test iteration may include 800,000 kernel executions. In an alternate embodiment, each kernel is executed using only a single data set or a subset of the multiple data sets.

In an embodiment, each data set includes a number of data values that may be consumed by a kernel. For example, if the kernel that consumes the most data will consume five data values during execution, then each data set may include up to five data values. Kernels within a set of multiple kernels may consume the same number or different numbers of data values.

In an embodiment, selected data sets are generated using one or more rules that produce data that is more likely to cause a marginal condition to occur during the test. These rules are referred to herein as “phenomenon-directed” data generation algorithms. In other embodiments, some or all data sets may be generated using random data generation algorithms and/or other data generation algorithms. An embodiment of a method for generating multiple data sets is described in more detail later in conjunction with FIG. 10.

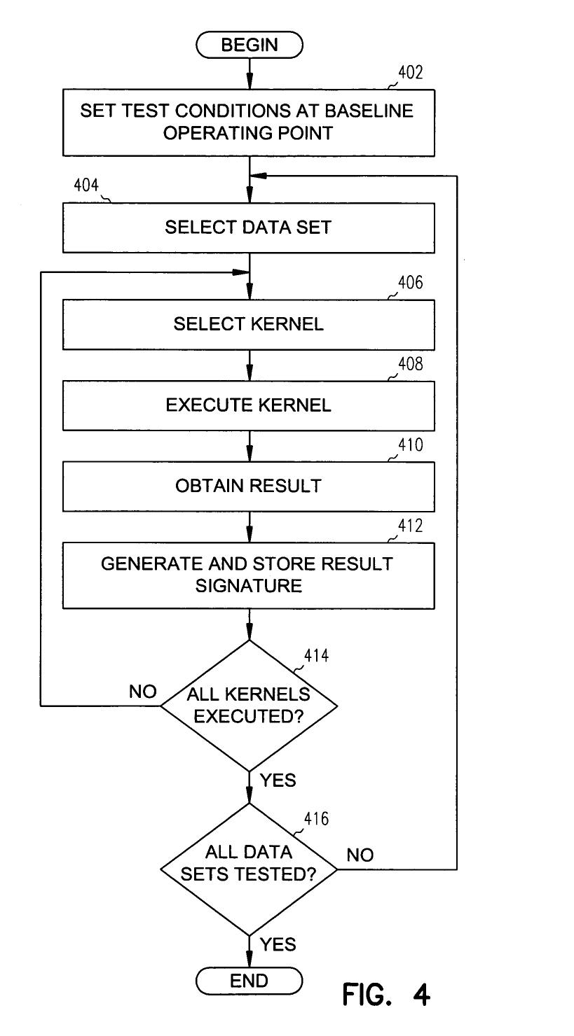

In block 308, a baseline test iteration is performed to establish baseline test results, which may be stored for future use. As will be described in more detail later in conjunction with FIG. 4, the baseline test iteration is performed using a selected device and an operating point that is not likely to result in detected marginal conditions. In an embodiment, a baseline test iteration is performed for each device that is included within the set of devices being tested. In another embodiment, baseline test iterations are performed for fewer than all of the devices being tested.

In an embodiment, the baseline test iteration produces one or more “result signatures.” A “result signature” is defined herein as a representation of one or more results produced by a DUT. In an embodiment, a result signature is a compressed or encoded version of one or more results. For example, but not by way of limitation, if it is expected that a kernel will produce results within four readable registers of the DUT, a result signature may be a combination (or other representation) of the values found in the four registers after executing the kernel. In alternate embodiments, result signatures may be produced using linear feedback shift registers, and/or other methods of producing a result signature. In still another embodiment, a result signature may represent the raw result information in an uncompressed form. Baseline result signatures are stored by the DUT (e.g., in one or more internal registers or caches, and/or in an external storage medium (e.g., medium 204, FIG. 2)), in an embodiment, for use during subsequent test iterations, as will be described in more detail below. The DUT may also or alternatively send the baseline result signatures to the test computer.

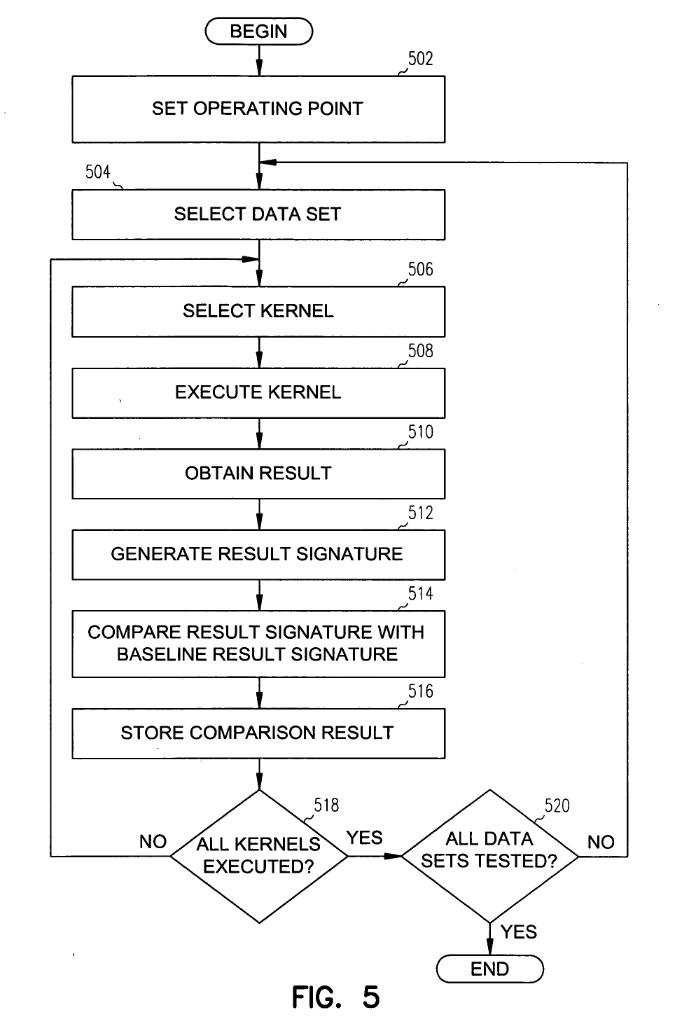

In block 310, a non-baseline test iteration is performed. This includes executing a test at a different operating point, in order to establish the additional, non-baseline result signatures. Various embodiments for conducting non-baseline test iterations are described later in more detail in conjunction with FIGS. 5-7. A non-baseline test iteration is substantially the same as a baseline test iteration, described briefly above in conjunction with block 308, except that a different operating point may be used. In addition, in various embodiments, a comparison is made between the baseline result signatures and the non-baseline result signatures during the non-baseline test iteration. This comparison facilitates detection of marginal conditions that may occur for the DUT at the given operating point. In an embodiment, the comparison is made by the DUT.

In block 312, a determination is made whether all test iterations have been completed. In other words, a determination is made whether the DUT has been tested over the operating point ranges established in block 302. If not, then a next test iteration is performed, in block 310, and the process continues until all test iterations have been completed. If all test iterations have been completed for the DUT (as determined in block 312), then in block 313, an additional determination is made whether all devices have been tested. If not, then a next baseline test is performed, in block 308, and the process iterates as illustrated. If so, then the process proceeds to block 314. In an embodiment, the determinations of blocks 312 and/or 313 may be made by a person that is overseeing the test.

In block 314, various test iterations and/or portions of test iterations may be re-performed, in an embodiment. This may be done to attempt to reproduce test results that occurred, and/or to re-generate test results that may not have been retained. For example, in an embodiment, not all test results and/or result signatures are retained through the end of a test iteration and/or through the entire testing process. Instead, test results for a test iteration may simply indicate that all or a portion of the test “passed” or “failed,” as was determined from the result signatures generated during the test iteration. If a test failed, and the result signatures are not available (e.g., they were not retained), the test iteration may be repeated, in block 314, to reproduce result signatures that may provide more detailed information to enable the marginal condition to be identified. In an alternate embodiment, re-performance of test iterations and/or portions thereof may not be included in the test process. Ultimately, some or all of the test results are sent to the test computer, to enable the test computer to indicate the results to a test analyst.

In block 316, unacceptable marginal conditions are identified and evaluated, in an embodiment. This process may be performed manually by one or more people, and/or all or portions of the process may be performed using various data analysis tools. As will be described in more detail later, “marginality mechanism” information is retained during execution of the test iterations (i.e., block 310) so that it is possible later to determine the device and test conditions that produced the marginal condition. The term “marginality mechanism” is defined herein as a set of process variation(s), operating point parameter(s), kernel(s), and/or data set(s) that produced a marginal condition (e.g., a failure or out-of-tolerance performance).

In an embodiment, the marginality mechanism information may be evaluated across test iterations to determine if particular process variations, operating point parameters, kernels, and/or data sets appear to be more likely to produce the marginal condition. The test conditions may be duplicated in an attempt to reproduce the marginal condition. During that time, further measurements and analyses of the DUT may be made. In addition, the kernel instructions and/or the data values for the failing kernel/data set combinations can be analyzed to pinpoint the DUT paths that were likely activated during the marginal condition.

In block 318, information obtained during the analysis process (block 316) may be used to make design modifications, if desired. For example, if a particular data transition produced unacceptable noise between adjacent paths, the distances between the paths may be modified to reduce the likelihood that the transition would continue to produce unacceptable noise. Alternatively, if a path length is too long, which results in unacceptable signal propagation times, the design may be modified to reduce the path length. Paths can be widened, narrowed, re-positioned, or otherwise modified to alter the path propagation, inductance, capacitance, and noise characteristics. Similar and additional design issues may be detected and compensated for during the process, including the detection of electrical element failures (e.g., capacitors, resistors, transistors, etc.).

The method of FIG. 3 then ends. After modifying the design and generating new devices, the process depicted in FIG. 3 may be repeated. This iterative test and design modification procedure can be repeated until a design is produced for which unacceptable marginal conditions are eliminated or reduced to tolerable levels. Various modifications to the order of execution of the blocks of FIG. 3 may be apparent to those of ordinary skill in the art, based on the description herein. Such modifications are intended to fall within the scope of embodiments of the described subject matter.

FIG. 4 illustrates a flowchart of a procedure for establishing baseline test results (e.g., block 308, FIG. 3), in accordance with an embodiment. The method begins, in block 402, by setting test conditions at a baseline operating point. This includes inserting a DUT into the test system, and setting the test operating point. Desirably, a device is selected that was not subjected to extreme process variations (e.g., significant skews, layer thickness variations, etc.) during manufacture. A “baseline operating point” is an operating point that is expected to produce relatively few detected marginal conditions, when compared with operating points with values toward the extremes of the test ranges. In an embodiment, for the baseline test, an operating point is selected that is thought to be likely to produce near optimal performance for the particular design. After the baseline operating point is established, a test computer may cause the DUT to execute a baseline test, which includes blocks 404 through 416.

In block 404, the DUT selects a data set from the multiple data sets previously generated (e.g., in block 306, FIG. 3). In an alternate embodiment, one or more data sets may be generated during the process of FIG. 4 (or FIGS. 5-7). A data set may have from one to many values. In an embodiment, the number of values within a data set is approximately the number of data values used by the kernel that will consume the most data. Examples of several data sets are given below in Table 1.

TABLE 1
Data Set Examples

| | Data Set 1 | Data Set 2 | Data Set 3 | Data Set 4 |
|---|---|---|---|---|
| D1 | 00100100 | 01111110 | 11100111 | 10101010 |
| D2 | 11011011 | 10000001 | 11100111 | 01111110 |
| D3 | 00100100 | 01111110 | 00000000 | 10000001 |

Although Table 1 illustrates four data sets, each with three data values, and each having 8 bits per value, in other embodiments, more data sets may be available, each data set may have more or fewer values, and each data value may have more or fewer than 8 bits. The data sets illustrated in Table 1 are for example purposes only.

In block 406, the DUT selects a test kernel from the multiple kernels previously generated (e.g., in block 304, FIG. 3). In an alternate embodiment, one or more kernels may be generated during the process of FIG. 4 (or FIGS. 5-7). In an embodiment, each kernel uses (e.g., consumes) one or more data values. Examples of two kernels are given below in Table 2.

TABLE 2
Kernel Examples

| Kernel 1 | Kernel 2 |
|---|---|
| RESULT1 = D1 + D2; | REGISTER1 = D1; |
| RESULT2 = RESULT1 + D3; | REGISTER1 = D2; |
| STORE RESULT2 AT 0xFFF018FF | REGISTER1 = D3 |

Although Table 2 illustrates two kernels, each having specific instructions, in other embodiments, more kernels may be available, and each kernel may have more, fewer, or different instructions. The kernels illustrated in Table 2 are for example purposes only.

In block 408, the DUT executes the selected kernel using the selected data set. For example, Kernel 1 (Table 2) may be executed using Data Set 1 (Table 1). As discussed previously, this causes one or more portions of the DUT to be activated.

In block 410, one or more results of the kernel execution are obtained from within the DUT (e.g., from DUT registers, I/O ports, and/or storage locations). For example, a result of Kernel 1 may be present within one or more DUT registers.

In block 412, the DUT generates and stores a result signature, in an embodiment. As described previously, a result signature may include a compressed or encoded version of one or more results. For example, a result signature produced in conjunction with Kernel 2 may include the sum of the values in Register1, Register2, and Register3. A result signature may be some other type of combination (or other representation) of the result value(s) produced in response to executing the kernel. In an alternate embodiment, a result signature may represent the raw result information in an uncompressed form. Baseline result signatures are stored, in an embodiment, for use during subsequent test iterations. In an embodiment, baseline result signatures are stored internally to the DUT. In another embodiment, baseline result signatures are stored externally to the DUT.

In block 414, a determination is made whether all kernels have been executed. If not, then the procedure iterates as shown, executing a next selected kernel for the same data set.

If all kernels have been executed for the given data set, then a determination is made, in block 416, whether all data sets have been tested. If not, then the procedure iterates as shown, selecting a next data set and executing each of the kernels in the set of kernels using that next data set.

After all data sets have been tested, the method ends. In the embodiment illustrated in FIG. 4, the inner loop (blocks 406-414) steps through the kernels in the set of multiple kernels, and the outer loop (blocks 404-416) steps through the data sets in the multiple data sets. Accordingly, during one iteration, all kernels are executed for a data set, then during a next iteration, all kernels are executed for another data set. In an alternate embodiment, the inner loop may step through the data sets and the outer loop may step through the kernels. In other words, during a first iteration, a kernel is repeatedly executed using different data each time, then during a next iteration, a different kernel is repeatedly executed using different data each time. Other modifications to the order of execution of the blocks of FIG. 4 may be apparent to those of ordinary skill in the art, based on the description herein. Such modifications are intended to fall within the scope of embodiments of the described subject matter, and may also apply to the flowcharts illustrate in FIGS. 5-7.

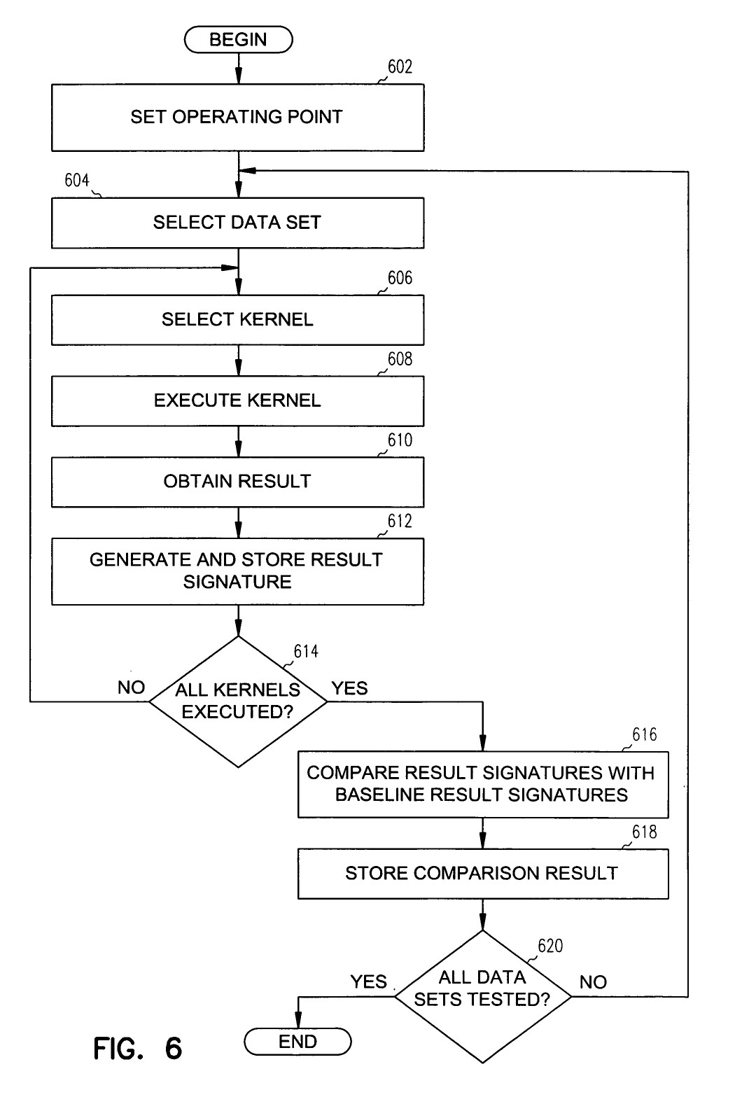

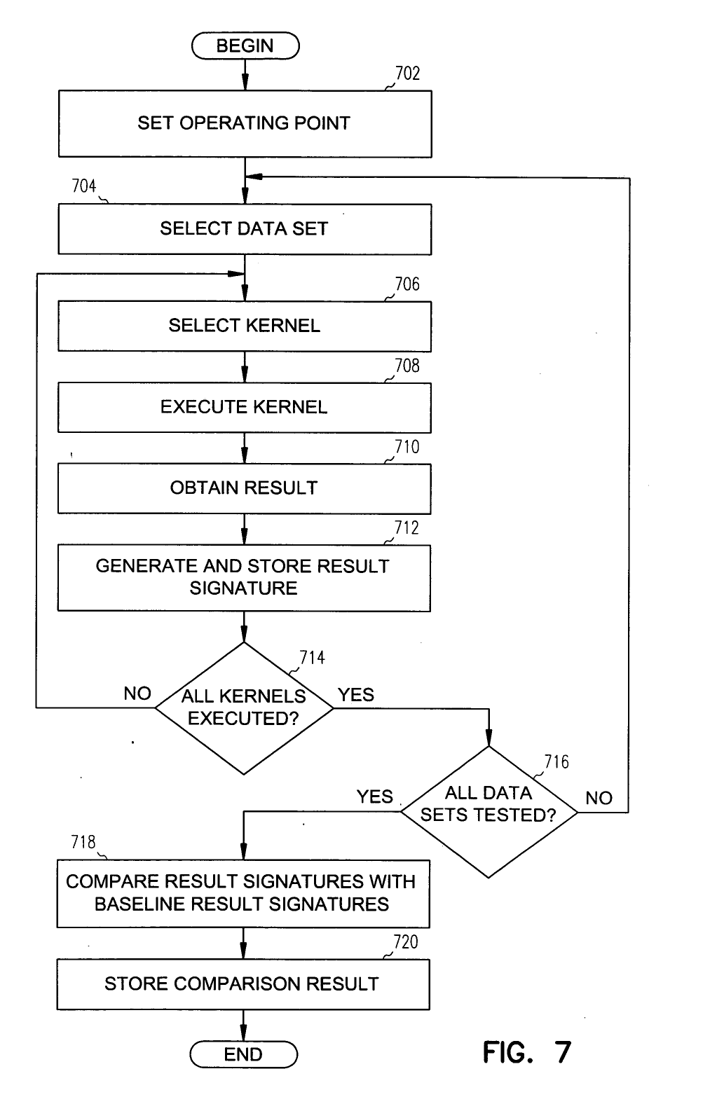

FIGS. 5-7 illustrate several embodiments of procedures for conducting additional testing to detect marginal conditions. Each of these embodiments is similar to the baseline test procedure illustrated in FIG. 4, except that they additionally compare their test results to the baseline test results. When the results do not match, then a marginal circuit condition may exist. Differences between the procedures of FIGS. 5-7 lie mainly in the timing of when the test result comparison occurs. In the flowchart of FIG. 5, the comparison occurs within the inner loop (e.g., after each kernel execution). In the flowchart of FIG. 6, the comparison occurs within the outer loop (e.g., after all kernels have been executed for a particular data set). Finally, in the flowchart of FIG. 7, the comparison occurs after completion of the iteration (e.g., after all kernels have been executed for all data sets). Each of these embodiments is described in more detail, below.

FIG. 5 illustrates a flowchart of a procedure for performing a non-baseline test iteration (e.g., block 310, FIG. 3), in accordance with an embodiment. The method begins, in block 502, by setting test conditions at a particular operating point. This includes inserting a DUT into the test system, if the DUT is not already inserted, and setting the test operating point. In an embodiment, for a non-baseline test, operating points that are selected earlier in the sequence of test iterations may be closer to the baseline operating point. This enables marginal conditions that occur close to the baseline operating point to be detected early in the test process. After the baseline operating point is established, a test computer may cause the DUT to execute a baseline test, which includes blocks 504 through 520.

In block 504, a data set is selected from the multiple data sets previously generated (e.g., in block 306, FIG. 3). In an alternate embodiment, one or more data sets may be generated during the process of FIG. 5. In an embodiment, the data sets and the sequence of their selection is the same for each of the non-baseline test iterations as it was for the baseline test iteration.

In block 506, a test kernel is selected from the multiple kernels previously generated (e.g., in block 304, FIG. 3). In an alternate embodiment, one or more kernels may be generated during the process of FIG. 5. In an embodiment, the test kernels and the sequence of their selection is the same for each of the non-baseline test iterations as it was for the baseline test iteration.

In block 508, the selected kernel is executed using the selected data set. This causes one or more portions of the DUT to be activated.

In block 510, one or more results of the kernel execution are obtained by receiving information present within the DUT. And in block 512, a result signature is generated from the obtained results, in an embodiment. As described previously, a result signature may include a compressed or encoded version of one or more results produced by the DUT.

In block 514, the DUT compares the result signature for the kernel/data set combination with a corresponding baseline result signature. The corresponding baseline result signature is a result signature produced during the baseline test (e.g., in block 412, FIG. 4) using the same kernel/data set combination.

When the comparison indicates that the result signatures correspond to the same produced results during the baseline and non-baseline tests, then it may be assumed that a marginal condition did not occur for the kernel/data set combination during the non-baseline test. Thus the comparison result is a “pass” condition. When the comparison indicates that the result signatures correspond to different results during the baseline and non-baseline tests, then it may be assumed that a marginal condition did occur for the kernel/data set combination during the non-baseline test. Thus the comparison result is a “fail” condition. In actuality, it is possible that the marginal condition occurred during the baseline test, and not during the non-baseline test, thus yielding the inconsistent results. However, in an embodiment, if an inconsistency exists, the initial presumption is that the marginal condition occurred during the non-baseline test.

In block 516 the comparison result is stored. In an embodiment, all comparison results are stored, regardless of whether the result is a “pass” or a “fail.” In another embodiment, only the “fail” type comparison results are stored. In still anther embodiment, the comparison result is sent by the DUT to the test computer, which may then evaluate the comparison.

The comparison result includes some or all of the following information, in an embodiment: 1) a pass or fail indication; 2) a kernel identifier; 3) a data set identifier; and 4) operating point information. The pass or fail indication indicates whether the kernel/data set combination produced a pass or a fail condition, when executed. In another embodiment, where only fail type comparison results are stored or sent to the test computer, this indication field may be excluded, as an assumption exists that all stored comparison results are fail type results.

The kernel identifier may include any of a variety of types of information that enable the kernel to be later identified. In an embodiment, each kernel may have an identifier value that is unique to the kernel, and this value may be stored. In another embodiment, a value may be stored that indicates when, in the sequence of kernel executions, the kernel was executed (e.g., an iteration number or a sequence number). In still another embodiment, the kernel itself may be stored. Other ways of identifying a kernel also may be used, as would be apparent to those of ordinary skill in the art, based on the description herein.

Similar to the kernel identifier, the data set identifier may include any of a variety of types of information that enable the data set to be later identified. In an embodiment, each data set may have an identifier value that is unique to the data set, and this value may be stored. In another embodiment, a value may be stored that indicates when, in the sequence of data set selections, the data set was selected (e.g., an iteration number or a sequence number). In still another embodiment, the data set itself may be stored, in a compressed or uncompressed format. Other ways of identifying a data set also may be used, as would be apparent to those of ordinary skill in the art, based on the description herein.

Operating point information enables one to later determine what operating point and/or device was used when a marginal condition occurred. In an embodiment, the operating point information may include a test iteration identifier, which may be correlated with other information to determine the operating point and/or the device identifier. In another embodiment, the operating point information may include one or more values indicating the actual operating point settings. Other ways of identifying the operating point information and/or device identifier also may be used, as would be apparent to those of ordinary skill in the art, based on the description herein.

In block 518, a determination is made whether all kernels have been executed. If not, then the procedure iterates as shown, executing a next selected kernel for the same data set. If all kernels have been executed for the given data set, then a determination is made, in block 520, whether all data sets have been tested. If not, then the procedure iterates as shown, selecting a next data set and executing each of the kernels in the set of kernels using that next data set. After all data sets have been tested, the method ends.

FIG. 6 illustrates a flowchart of a procedure for performing a non-baseline test iteration (e.g., block 310, FIG. 3), in accordance with another embodiment. The method begins, in block 602, by setting an operating point for the non-baseline test. Block 602 is substantially similar to block 502 (FIG. 5). In addition, blocks 604, 606, 608, and 610 are substantially similar to blocks 504, 506, 508, and 510 (FIG. 5), respectfully. For the purposes of brevity, the details of those blocks are not reiterated here. Instead, the remaining blocks are discussed in more detail to accentuate the differences between the procedure of FIGS. 5 and 6.

The procedure illustrated in FIG. 6 diverges from the procedure illustrated in FIG. 5 in block 612, which includes generating and storing the result signature, based on the results obtained from the DUT. In an embodiment, the result signature may be stored short term, as it may be evaluated prior to the end of the test iteration. Rather than comparing the non-baseline result signature with the baseline result signature for each kernel/data set combination within the inner loop (as was done in the procedure of FIG. 5), the non-baseline result signatures are evaluated later, as will be described below.

The term “kernel execution series” is used herein to mean a group of kernel executions that includes execution of each kernel of the set of multiple kernels for a single data set. In block 614, a determination is made whether all kernels have been executed (i.e., whether a kernel execution series has been completed). If not, then the procedure iterates as shown, executing a next selected kernel for the same data set (i.e., within the same kernel execution series).

If all kernels have been executed for the selected data set (i.e., the kernel execution series is completed), then, in block 616, the result signatures produced during the kernel execution series are compared with corresponding baseline result signatures. The corresponding baseline result signatures are result signatures, produced during the baseline test (e.g., in block 412, FIG. 4) using the same kernel/data set combinations. Accordingly, multiple comparisons may be made during block 616 (e.g., one comparison per kernel/data set combination). In an alternate embodiment, the multiple result signatures may be compressed (e.g., added, checksum, or some other compression method), and the compressed result signature set(s) may be compared.

If the comparisons indicate that the result signatures correspond to the same results produced during the baseline and non-baseline tests, then it may be assumed that a marginal condition did not occur during the non-baseline kernel execution series. Thus, each of the comparison results is a “pass” type result. When the comparisons indicate that one or more result signatures correspond to different results during the baseline and non-baseline tests, then it may be assumed that one or more marginal conditions did occur during the non-baseline kernel execution series. Thus one or more comparison results are a “fail” type result.

In block 618 the comparison results are stored and/or sent to the test computer, which may then evaluate the comparison. In an embodiment, all comparison results are stored, regardless of whether the result is a “pass” or a “fail” type result. In another embodiment, only the “fail” type comparison results are stored. In still another embodiment, rather than storing a comparison result for each kernel/data set combination, a compressed result may be stored for each kernel execution series. For example, if none of the kernel/data set combinations executed during a kernel execution series produced a “fail” type result, then a single comparison result may be stored, indicating a “pass” condition (or no result may be stored) for the entire kernel execution series.

If one or more kernel/data set combinations produced during the kernel execution series indicates a “fail” type result, then a single comparison result (or at least fewer than a full set of results) may be stored and/or sent to the test computer, indicating a “fail” condition. Storing less than a full set of results reduces the amount of comparison result information that is stored during a test iteration. If a failing condition did occur at some time during the kernel execution series, then the kernel execution series (or a portion thereof) may be re-performed later (e.g., in block 314, FIG. 3), to more accurately identify the failure mechanism.

In block 620, a determination is made whether all data sets have been tested. If not, then the procedure iterates as shown, selecting a next data set and executing each of the kernels in the set of kernels using that next data set. After all data sets have been tested, the method ends.

FIG. 7 illustrates a flowchart of a procedure for performing a non-baseline test iteration (e.g., block 310, FIG. 3), in accordance with another embodiment. The method begins, in block 702, by setting an operating point for the non-baseline test. Block 702 is substantially similar to block 602 (FIG. 6). In addition, blocks 704, 706, 708, 710, 712, and 714 are substantially similar to blocks 604, 606, 608, 610, 612, and 614 (FIG. 6), respectfully. For the purposes of brevity, the details of those blocks are not reiterated here. Instead, the remaining blocks are discussed in more detail to accentuate the differences between the procedure of FIGS. 6 and 7.

The procedure illustrated in FIG. 7 diverges from the procedure illustrated in FIG. 6 in block 716, makes a determination of whether all data sets have been tested earlier than the decision made in FIG. 6 (i.e., in block 620). If all data sets have not been tested, then the procedure iterates as shown, selecting a next data set and executing each of the kernels in the set of kernels using that next data set.

If all data sets have been tested, then in block 718, the result signatures produced during the multiple kernel execution series are compared with corresponding baseline result signatures. The corresponding baseline result signatures are result signatures produced during the baseline test (e.g., in block 412, FIG. 4) using the same kernel/data set combinations. Accordingly, multiple comparisons may be made during block 718 (e.g., one comparison per kernel/data set combination). In an alternate embodiment, the multiple result signatures may be compressed (e.g., added, checksum, or some other compression method), and the compressed result signature set(s) may be compared.

If the comparisons indicate that the result signatures correspond to the same results produced during the baseline and non-baseline tests, then it may be assumed that a marginal condition did not occur during the multiple, non-baseline kernel execution series. Thus, each of the comparison results is a “pass” type result. When the comparisons indicate that one or more result signatures correspond to different results during the baseline and non-baseline tests, then it may be assumed that one or more marginal conditions did occur during one or more of the multiple, non-baseline kernel execution series. Thus one or more comparison results are a “fail” type result.

In block 720 the comparison results are stored and/or sent to the test computer, which may then evaluate the comparison. In an embodiment, all comparison results are stored, regardless of whether the result is a “pass” or a “fail” type result. In another embodiment, only the “fail” type comparison results are stored. In still another embodiment, rather than storing a comparison result for each kernel/data set combination, a compressed result may be stored for each kernel execution series. In still another embodiment, a compressed result may be stored for the entire test iteration (e.g., for all of the multiple kernel execution series). For example, if none of the kernel/data set combinations executed during the multiple kernel execution series produced a “fail” type result, then a single comparison result may be stored, indicating a “pass” condition (or no result may be stored) for the entire test iteration.

If one or more kernel/data set combinations produced during the multiple kernel execution series indicates a “fail” type result, then a single comparison result (or at least fewer than a full set of results) may be stored, indicating a “fail” condition. Storing less than a full set of results reduces the amount of comparison result information that is stored during a test iteration. If a failing condition did occur at some time during the multiple kernel execution series, then one or more kernel execution series (or portions thereof) may be re-performed later (e.g., in block 314, FIG. 3), to more accurately identify the failure mechanism. The method then ends.

Referring back to FIG. 3, after a test iteration is completed (e.g., as determined in block 312), and any portions of the test are re-performed, an evaluation of marginal conditions may be made (e.g., in block 316). This evaluation may be made by a person who reviews the stored test comparison information, or all or portions of the evaluation may be performed using software.

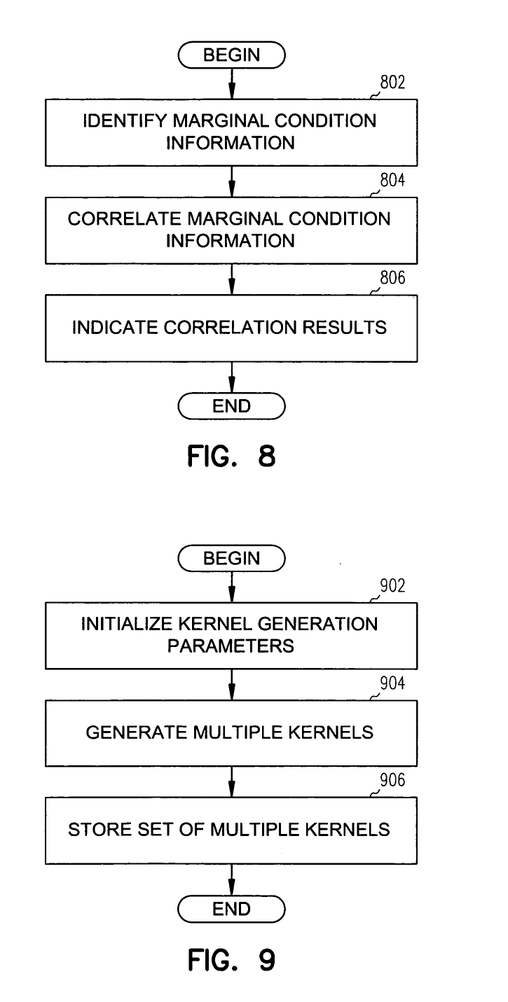

FIG. 8 illustrates a flowchart of a procedure for evaluating marginal conditions (e.g., block 316, FIG. 3), in accordance with an embodiment. The method begins, in block 802, by identifying information relating to all detected marginal conditions. In an embodiment, this includes locating information for which a “fail” type comparison occurred, and determining some or all of the following from the information: 1) device identifier; 2) operating point parameters; 3) kernel during which marginal condition occurred; and/or 4) data set for which marginal condition occurred.

In an embodiment, the information associated with the detected marginal conditions is correlated, in block 804. This correlation may yield further information to indicate whether a particular process or other operating point parameter is more likely to produce a marginal condition. In addition, this correlation may yield information indicating that one or more kernels and/or one or more data sets are more likely to produce a marginal condition.

In block 806, the correlation results are stored or otherwise indicated. This enables a person reviewing the test results to have additional information that may be helpful in further analyzing detected marginal conditions, and in pinpointing sub-standard areas in the design. The method then ends.

Also as described previously in conjunction with FIG. 3, embodiments of the method include generating multiple test kernels (block 304) and generating multiple data sets (block 306). Embodiments of procedures for these actions are illustrated in FIGS. 9 and 10, respectively.

FIG. 9 illustrates a flowchart of a procedure for generating test kernels (e.g., block 304, FIG. 3), in accordance with an embodiment. In an embodiment, the method begins by initializing kernel generation parameters, in block 902. Kernel generation parameters may include, for example, parameters selected from a group of parameters that includes: 1) target device type; 2) number of kernels in kernel group; 3) kernel size parameter; 4) data usage parameter; 5) other rules; and 6) seed value(s).

The target device type may enable the kernel generation process to determine allowed instructions and various rules that are relevant to generating code to be executed on the target device. The number of kernels in the kernel group indicates how many kernels the process should generate. In an embodiment, a group of kernels used during a test iteration may include 100 or more kernels. In other embodiments, fewer kernels may be used. The kernel size parameter may include a fixed number of instructions (or bytes) that each kernel should include. Alternatively, the kernel size parameter may specify a maximum or minimum number of instructions (or bytes). In an embodiment, each kernel includes a relatively small activation sequence that includes twenty or fewer instructions. In other embodiments, larger activation sequences could be used. In another embodiment, each kernel includes instructions to activate only one conductive path within the DUT, or a set of related conductive paths (e.g., adjacent address or data lines) within the DUT. The data usage parameter may indicate how many data values (or bits/bytes) each kernel should use. Alternatively, the data usage parameter may specify a maximum or minimum number of data values (or bits/bytes) each kernel should use. Other rules for the kernel generation process may be specified as well, such as, types of instructions to use, address ranges, data ranges, information particular to the device type, and the like.

In an embodiment, the kernel instructions and/or the kernels themselves are subjected to a randomization process. If a randomization process is used, a randomization seed value may be specified or generated. Randomization may be used to randomly select instructions for a kernel from a set of instructions. In addition or alternatively, randomization may be used to modify the order of the kernels within the kernel set. In an embodiment, the seed value is retained to enable the kernels to be re-generated at a later time, if desired. In other embodiments, the kernels may not be subjected to a randomization process, but instead their generation and/or ordering may be more deliberate.

In block 904, multiple kernels are generated in accordance with the kernel generation parameters. As discussed previously, generation of the kernel instructions and/or the ordering of the kernels within a set of kernels may (or may not) be subjected to randomization.

In block 906, the multiple kernels are stored for use during the test process. The method then ends.

FIG. 10 illustrates a flowchart of a procedure for generating test data (e.g., block 306, FIG. 3), in accordance with an embodiment. In an embodiment, the method begins by initializing data set generation parameters, in block 1002. Data set generation parameters may include, for example, parameters selected from a group of parameters that includes: 1) target device type; 2) number of data sets in the data set group; 3) data length parameter; 4) data set size parameter; 5) data range(s); 6) other rules; and 7) seed value(s).

The target device type may enable the data set generation process to determine allowed data types and sizes and various rules that are relevant to generating data for use by the target device. The number of data sets in the data set group indicates how many data sets the process should generate. In an embodiment, a group of data sets used during a test iteration may include 1000 or more data sets. In other embodiments, fewer data sets may be used. The data length parameter may indicate the length of each data value and/or address value. The data set size parameter may include a fixed number of data values (or bytes) that each data set should include. Alternatively, the data set size parameter may specify a maximum or minimum number of data values (or bytes). In an embodiment, each data set includes twenty or fewer data values. In other embodiments, larger data sets could be used. The data range parameter may indicate one or more allowable ranges for generated data and/or addresses. Other rules for the data set generation process may be specified as well, such as, types of data to use, information particular to the device type, and the like.

In an embodiment, all or parts of the data set generation process may include randomization processes. If a randomization process is used, a randomization seed value may be specified or generated. Randomization may be used to randomly select data bits and/or values. In addition or alternatively, randomization may be used to modify the order of the data values and or the data sets. In an embodiment, the seed value is retained to enable the data sets to be re-generated at a later time, if desired. In other embodiments, data set generation may not be subjected to a randomization process, but instead their generation and/or ordering may be more deliberate.

In blocks 1004-1006, a data set is generated. In an embodiment, a first data value for the data set is generated in block 1004. In an embodiment, the first data value, or portions thereof, may be generated in a random manner. In another embodiment, one or more rules may be employed in determining the data value (e.g., data ranges, certain bit values, etc.). In still another embodiment, the first data value may be deliberately selected based on some criteria.

In block 1006, one or more additional data values for the data set are generated (assuming the data set has more than one value). In an embodiment, one or more “phenomenon-directed” data generation algorithms are used in generating the one or more additional data values (and/or in generating the first data value). A “phenomenon-directed” data generation algorithm is a data generation algorithm that is designed to generate data values that, when applied to a DUT, increase the likelihood that certain electrical phenomenon may occur or may be made worse. In an embodiment, these electrical phenomenon are phenomenon that may increase the likelihood of a marginal condition occurring. For example, but not by way of limitation, carry propagation errors, noise coupling, and addressing misses, to name a few, may be affected by the data and/or addresses that are being used for a particular operation or sequence of operations.

In an embodiment, one or more of several available phenomenon-directed data generation algorithms may be selected for use in generating one or more data values. In an embodiment, a phenomenon-directed data generation algorithm is selected from a set of algorithms that includes a multiple-wire algorithm, a carry-propagation algorithm, and a near-miss algorithm

A “multiple-wire” algorithm is an algorithm that is intended to exacerbate noise coupling between adjacent address or data lines. In various embodiments, a 3-wire or 5-wire model may be used to generate sequential data values that result in specific transitions to occur on adjacent address or data lines. For example, a multiple-wire algorithm may generate data that causes opposite transitions to occur between adjacent lines. In an embodiment, one line is identified as a “victim line,” and one or more other lines are identified as “aggressor lines.” A victim line may correspond to a bit location in a data value. For example, a victim line may be identified as bit 4. Aggressor lines may correspond to bit location(s) adjacent to the victim bit location. For example, in a 3-wire model, aggressor lines may correspond to bits 3 and 5 (with bit 4 being the victim), and in a 5-wire model, aggressor lines may correspond to bits 2, 3, 5, and 6.

After a first data value is selected (either randomly or non-randomly), subsequent data values may be selected to increase the likelihood that the value on the victim wire will be corrupted by the transitions on the aggressor wire(s). For example, using a 5-wire model where bit 4 is the victim and bits 2, 3, 5 and 6 are the aggressors, a multiple-wire algorithm may generate the following sequence:

| | Bit 0 | Bit 1 | Bit 2 | Bit 3 | Bit 4 | Bit 5 | Bit 6 | Bit 7 |
|---|---|---|---|---|---|---|---|---|
| Value 1 | 0 | 0 | 1 | 1 | 0 | 1 | 1 | 0 |
| Value 2 | 0 | 0 | 0 | 0 | 1 | 0 | 0 | 0 |
| Value 3 | 0 | 0 | 1 | 1 | 0 | 1 | 1 | 0 |

In the above sequence, bits 2, 3, 5, and 6 transition oppositely from bit 4 from value 1 to value 2, and again from value 2 to value 3. In theory, this may exacerbate noise coupling between the lines, and cause an erroneous value on the line corresponding to bit 4.

The multiple-wire data generation algorithm may include information regarding when and where line inversions may exist within the design. Accordingly, the process may select logical data values that transition differently from the intended electrical values.

A “carry-propagation” algorithm is an algorithm that is intended to increase the likelihood that a carry-propagation error will occur. For example, an addition instruction executed with data having a long carry chain may be relatively slow, due to propagation of carry bits. The same instruction executed with data having a shorter carry chain may execute substantially faster. When carry information is to be propagated through more bits, the instruction may take too long to execute, thus causing a failure. In an embodiment, a carry-propagation algorithm may generate one or more data values that include relatively large sections of “0”s or “1”s, for example, so that when those values are added with other values, the likelihood for multiple-bit carry propagation increases.

A “near-miss” algorithm is an algorithm that is intended to increase the likelihood that an addressing error will occur. A near-miss error may occur, for example, when one address should result in accessing data in one device (e.g., a cache) and a similar address (e.g., one bit different) should result in accessing data in another device (e.g., RAM). If the distinguishing bit (or bits) is corrupted, an address hit error may occur. In an embodiment, a near-miss algorithm may generate one or more values that access a first storage medium segment, and then generate a value that modifies the distinguishing bit. If, during testing, the bit modification does not result in accessing a second storage medium segment, then a near-miss error occurs.

Referring again to FIG. 10, a determination is made, in block 1008, whether more data sets are to be generated. If so, then the procedure iterates as illustrated. If not, then the method ends.

Thus, various embodiments of a method, apparatus, and system have been described for testing integrated circuits. The foregoing description of specific embodiments reveals the general nature of the described subject matter sufficiently that others can, by applying current knowledge, readily modify and/or adapt it for various applications without departing from the generic concept. Therefore such adaptations and modifications are within the meaning and range of equivalents of the disclosed embodiments. The phraseology or terminology employed herein is for the purpose of description and not of limitation. Accordingly, the described subject matter embraces all such alternatives, modifications, equivalents and variations as fall within the spirit and broad scope of the appended claims.

The various procedures described herein can be implemented in hardware, firmware or software. A software implementation may use microcode, assembly language code, or a higher-level language code. The code may be stored on one or more volatile or non-volatile computer-readable media during execution or at other times. These computer-readable media may include hard disks, removable magnetic disks, removable optical disks, magnetic cassettes, flash memory cards, digital video disks, Bernoulli cartridges, RAMs, ROMs, and the like.

1. A method comprising:
selecting a data set from a set of multiple data sets;
selecting a test kernel from a set of multiple test kernels, wherein the test kernel includes one or more instructions that utilize data;
executing the test kernel, by a device under test, with at least some of the data from the data set;
obtaining a test result as one or more results generated by the device under test in response to the executing; and
repeating the selecting a data set, selecting a test kernel, executing the test kernel, and obtaining a test result for one or more remaining test kernels in the set of multiple test kernels and for one or more remaining data sets in the set of multiple data sets.

2. The method of claim 1, wherein selecting the data set comprises:
selecting the data set from a set of at least 1000 data sets, wherein selected ones of the data sets include twenty or fewer data values.

3. The method of claim 1, wherein selecting the test kernel comprises:
selecting the test kernel from a set of at least 100 test kernels, wherein selected ones of the test kernels include twenty or fewer lines of instructions.

4. The method of claim 1, further comprising:
generating the set of multiple data sets.

5. The method of claim 1, further comprising:
generating the set of multiple test kernels.

6. The method of claim 1, further comprising:
generating a result signature from the test result.

7. The method of claim 6, further comprising:
comparing the result signature with a baseline result signature; and
storing a comparison result, which indicates whether or not the result signature and the baseline result signature are identical.

8. The method of claim 1, further comprising:
establishing a first set of test conditions prior to executing the test kernel.

9. The method of claim 8, further comprising:
establishing a second set of test conditions after repeating the selecting a data set, selecting a test kernel, executing the test kernel, and obtaining a test result; and
again repeating the selecting a data set, selecting a test kernel, executing the test kernel, and obtaining a test result under the second set of test conditions.

10. A method comprising:
generating multiple test kernels, wherein a test kernel includes one or more instructions that utilize data;
generating multiple data sets;
causing a first test to be executed by a device under test under a first set of test conditions, wherein executing the first test includes executing the multiple test kernels using the multiple data sets, and wherein executing the first test results in generation of a set of baseline test results;
causing a second test to be executed by the device under test under a second set of test conditions, wherein executing the second test includes executing the multiple test kernels using the multiple data sets; and
evaluating a comparison between the baseline test results and results from the second test to identify unacceptable marginalities in a design of the device under test.

11. The method of claim 10, wherein generating the multiple test kernels comprises:
initializing kernel generation parameters for a kernel; and
generating multiple kernels in accordance with the kernel generation parameters, wherein selected ones of the kernels include activation sequences for causing the device under test to perform an action, and further include twenty or fewer lines of instructions.

12. The method of claim 10, wherein generating the multiple data sets comprises:
generating a first data value for a first data set; and
generating one or more additional data values using one or more phenomenon-directed data generation algorithms.

13. The method of claim 12, wherein generating the one or more additional data values comprises:
selecting an phenomenon-directed data generation algorithm from a set of algorithms that includes a multiple-wire algorithm, a carry-propagation algorithm, and a near-miss algorithm; and
generating the one or more additional data values using the selected phenomenon-directed data generation algorithm and the first data value.

14. The method of claim 10, wherein causing the first test to be executed comprises:
selecting a data set from the set of multiple data sets;
selecting a test kernel from the set of multiple test kernels;
executing the test kernel with at least some of the data from the data set, which causes one or more inputs to be provided to the device under test;
obtaining a test result as one or more results generated by the device under test in response to the executing;
repeating the selecting a data set, selecting a test kernel, executing the test kernel, and obtaining a test result for one or more remaining test kernels in the set of multiple test kernels and for one or more remaining data sets in the set of multiple data sets; and
storing the baseline test results, which are representative of the test result.

15. The method of claim 10, wherein causing the second test to be executed comprises:
selecting a data set from the set of multiple data sets;
selecting a test kernel from the set of multiple test kernels;
executing the test kernel with at least some of the data from the data set, which causes one or more inputs to be provided to the device under test;
obtaining a test result as one or more results generated by the device under test in response to the executing; and
repeating the selecting a data set, selecting a test kernel, executing the test kernel, and obtaining a test result for one or more remaining test kernels in the set of multiple test kernels and for one or more remaining data sets in the set of multiple data sets.

16. The method of claim 10, wherein:
causing the first test to be executed includes generating baseline result signatures for the kernels that are executed during the first test, and storing the baseline result signatures as the set of baseline test results;
causing the second test to be executed includes generating non-baseline result signatures for the kernels that are executed during the second test; and
evaluating the comparison includes comparing the baseline test result signatures with the non-baseline test result signatures.

17. The method of claim 10, wherein causing the second test to be executed comprises:
evaluating a failure indication, which indicates that, when executed, at least one data set/kernel combination produced a result that differed from the baseline test results; and
causing at least a portion of the second test to be re-executed to identify a specific data set and a specific kernel that corresponds with the failure indication.

18. The method of claim 10, further comprising:
establishing a different set of test conditions; and
causing another test to be executed by a device under test under the different set of test conditions, wherein executing the another test includes executing the multiple test kernels using the multiple data sets;
evaluating a comparison between the baseline test results and results from the another test; and
repeating the establishing the different set of test conditions, causing another test to be executed, and evaluating the comparison until the device under test has been tested for all sets of test conditions within a test series.

19. A computer readable medium having program instructions stored thereon to perform a method, which when executed within a test system, result in:
selecting a data set from a set of multiple data sets;
selecting a test kernel from a set of multiple test kernels, wherein the test kernel includes one or more instructions that utilize data;
executing the test kernel, by a device under test, with at least some of the data from the data set;
obtaining a test result as one or more results generated by the device under test in response to the executing; and
repeating the selecting a data set, selecting a test kernel, executing the test kernel, and obtaining a test result for each remaining test kernel in the set of multiple test kernels and for each remaining data set in the set of multiple data sets.

20. The computer readable medium of claim 19, wherein the program instructions, when executed, further result in:
generating a result signature from the test result.

21. The computer readable medium of claim 19, wherein the program instructions, when executed, further result in:
comparing the result signature with a baseline result signature; and
storing a comparison result, which indicates whether or not the result signature and the baseline result signature are identical.

22. The computer readable medium of claim 19, wherein the program instructions, when executed, further result in:
establishing a first set of test conditions prior to executing the test kernel.
establishing a second set of test conditions after repeating the selecting a data set, selecting a test kernel, executing the test kernel, and obtaining a test result; and
again repeating the selecting a data set, selecting a test kernel, executing the test kernel, and obtaining a test result under the second set of test conditions.

23. A computer readable medium having program instructions stored thereon to perform a method, which when executed within a test system, result in:
generating multiple test kernels, wherein a test kernel includes one or more instructions that utilize data;
generating multiple data sets;
causing a first test to be executed by a device under test under a first set of test conditions, wherein executing the first test includes executing the multiple test kernels using the multiple data sets, and wherein executing the first test results in generation of a set of baseline test results;
causing a second test to be executed by a device under test under a second set of test conditions, wherein executing the second test includes executing the multiple test kernels using the multiple data sets; and
evaluating a comparison between the baseline test results and results from the second test to identify unacceptable marginalities in a design of the device under test.

24. The computer readable medium of claim 23, wherein the program instructions, when executed, further result in generating the multiple test kernels by:
initializing kernel generation parameters for a kernel; and
generating multiple kernels in accordance with the kernel generation parameters, wherein selected ones of the kernels include activation sequences for causing the device under test to perform an action, and further include twenty or fewer lines of instructions.

25. The computer readable medium of claim 23, wherein the program instructions, when executed, further result in generating the multiple data sets by:
generating a first data value for a first data set; and
generating one or more additional data values using one or more phenomenon-directed data generation algorithms.

26. The computer readable medium of claim 23, wherein the program instructions, when executed, further result in executing the first test by:
selecting a data set from the set of multiple data sets;
selecting a test kernel from the set of multiple test kernels;
executing the test kernel with at least some of the data from the data set, which causes one or more inputs to be provided to the device under test;
obtaining a test result as one or more results generated by the device under test in response to the executing;
repeating the selecting a data set, selecting a test kernel, executing the test kernel, and obtaining a test result for each remaining test kernel in the set of multiple test kernels and for each remaining data set in the set of multiple data sets; and
storing the baseline test results, which are representative of the test result.

27. An apparatus comprising:
a computer that includes program instructions stored thereon to perform a method, which when executed result in
selecting a data set from a set of multiple data sets,
selecting a test kernel from a set of multiple test kernels, wherein the test kernel includes one or more instructions that utilize data,
executing the test kernel, by a device under test, with at least some of the data from the data set,
obtaining a test result as one or more results generated by the device under test in response to the executing, and
repeating the selecting a data set, selecting a test kernel, executing the test kernel, and obtaining a test result for each remaining test kernel in the set of multiple test kernels and for each remaining data set in the set of multiple data sets;
a socket that receives the device under test and includes socket contacts that contact device connectors of the device under test; and
one or more transmission media for supporting signal exchanges between the computer and the socket contacts.

28. The apparatus of claim 27, wherein the socket is a microprocessor socket.

29. An apparatus comprising:
a socket that receives a device under test;
a computer readable medium that includes program instructions stored thereon to perform a method, which when executed result in
selecting a data set from a set of multiple data sets,
selecting a test kernel from a set of multiple test kernels, wherein the test kernel includes one or more instructions that utilize data,
executing the test kernel, by the device under test, with at least some of the data from the data set,
obtaining a test result as one or more results generated by the device under test in response to the executing, and
repeating the selecting a data set, selecting a test kernel, executing the test kernel, and obtaining a test result for each remaining test kernel in the set of multiple test kernels and for each remaining data set in the set of multiple data sets.

30. The apparatus of claim 29, further comprising:
one or more adjustable devices, electrically coupled to the socket, which can be manipulated to vary test conditions to which the device under test is subjected.
